(19) United States
(12) Patent Application Publication
(10) Pub. No.: US 2006/0043538 A1
(43) Pub. Date: Mar. 2, 2006

(54) Bump structure of an opto-electronic chip

(75) Inventors: Yi-Chang Lee, Tainan (TW); An-Hong Liu, Tainan (TW); Yeong-Ching Chao, Tainan (TW); Yao-Jung Lee, Tainan (TW)

Correspondence Address: TROXELL LAW OFFICE PLLC, SUITE 1404, 5205 LEESBURG PIKE, FALLS CHURCH, VA, 22041, US

(73) Assignees: ChipMOS TECHNOLOGIES (Bermuda) LTD.; ChipMOS TECHNOLOGIES INC.

(21) Appl. No.: 11/208,595

(22) Filed: Aug. 23, 2005

(30) Foreign Application Priority Data
Aug. 24, 2004 (TW) 093213431

(51) Int. Cl. H01L 23/58; H01L 23/02

(52) U.S. Cl. 257/636; 257/678

(57) ABSTRACT

An opto-electronic chip includes a plurality of multi-level bumps thereon, each consisting of multiple plated layers. The opto-electronic chip has a plurality of bonding pads and an photoelectric effecting region on its active surface. Each multi-level bump comprises at least an electroless-plated nickel (Ni) layer and an electroless-plated gold (Au) layer wherein the nickel layers cover the bonding pads and the gold layers are formed on the tops of the nickel layers. Furthermore, the thickness of the nickel layers is larger than that of the gold layers. The UBM processes in conventional bumping processes are not needed so that the contaminations or damages to the photoelectric effecting region of the opto-electronic chip due to UBM can be eliminated.

### FIELD OF THE INVENTION

The present invention relates to an IC device with an opto-electronic chip, and more particularly, to a bump structure of an opto-electronic chip.

### BACKGROUND OF THE INVENTION

There are many kinds of opto-electronic chips in the market such as CMOS (Complementary Metal Oxide Semiconductor) image sensor chip (CIS), CDD (Charge-Coupled Device) CIS, LCOS (Liquid Crystal On Silicon) image projecting chip, and DLP (Digital Light Processing) image processing chip. One of the common features is that each has a photoelectric effecting region on the active surface of the opto-electronic chip to process the light in images. Up to now, wire bonding is still the major interconnection method between opto-electronic chips and their carrying substrates, therefore, the total package/module dimensions are often large which are not suitable for hand-held applications. In order to reduce the package/module dimensions, conventional bumping processes including eletroplating are implemented in wafer form. However, without any success since there is no protection on the photoelectric effecting regions of the opto-electronic chips. Moreover, those regions are very sensitive to contaminations or damages. The conventional bumping processes for conventional IC chips always include sputtering of UBM prior to electroplating of bumps. The exposed parts of the UBM should be etched off after the electroplating. During these bumping processes, the photoelectric effecting regions of the opto-electronic chips are susceptible to be contaminated or damaged leading to poor image qualities and image processing functions.

A cross-section view of a conventional bump integrated chip (IC) is shown in FIG. 1. A chip 10 has a plurality of bonding pads 12 on the active surface 11 which is fully covered by a passivation layer 13. UBM structures 20 are disposed on the bonding pads 12 first, then bumps 30, such as gold bumps or solder bumps, are formed on the UBM structures 20. The conventional bumping processes are described as follows. Multiple layers of UBM 20 are sputtered over the passivation layer 13. After photolithography processes, including photo resists forming, exposure, and development, the plurality of bumps 30 can be eletroplated on the UBM 20 and are aligned with the corresponding bonding pads 12. After photo resists stripping, an UBM etching is followed to form UBM pads 20. Finally, bumps are reflowed if necessary. The photoelectric effecting regions of opto-electronic chips can not go through all the bumping processes without any contaminations nor damages.

### SUMMARY OF THE INVENTION

The main purpose of the present invention is to provide a bump structure of an opto-electronic chip. A plurality of multi-level bumps are disposed on bonding pads on an active surface of an opto-electronic chip, each multi-level bump comprises at least an electroless-plated nickel layer and an electroless-plated gold layer. Therein, the nickel layers cover the bonding pads, and the gold layers are formed on tops of the nickel layers. Moreover, the thickness of the gold layers is smaller than that of the nickel layers. Since the opto-electronic chip is kept away from the UBM and reflowing process of the conventional bumping processes, therefore, any possible contaminations and damages are eliminated.

According to the present invention, an IC device comprises an opto-electronic chip and a plurality of multi-level bumps. The opto-electronic chip has an active surface with a plurality of bonding pads thereon. Moreover, the active surface includes a photoelectric effecting region. Each multi-level bump comprises at least an electroless-plated nickel layer and an electroless-plated gold layer wherein the nickel layers cover the bonding pads, and the gold layers are formed on tops of the nickel layers. The thickness of the gold layers is smaller than that of the nickel layers. Multi-level bumps are formed through electroless-plating processes without conventional UBM and reflowing processes, therefore, the contaminations or damages to the photoelectric effecting region of an opto-electronic chip can be eliminated.

### DESCRIPTION OF THE DRAWINGS

FIG. 1 is a cross-sectional view of a conventional bump integrated chip.

FIG. 2 is a cross-sectional view of the bump structure of an opto-electronic chip according to one embodiment of the present invention.

FIG. 3A to FIG. 3C are the cross-sectional views of the bump structure during fabrication processes according to the preferred embodiment of the present invention.

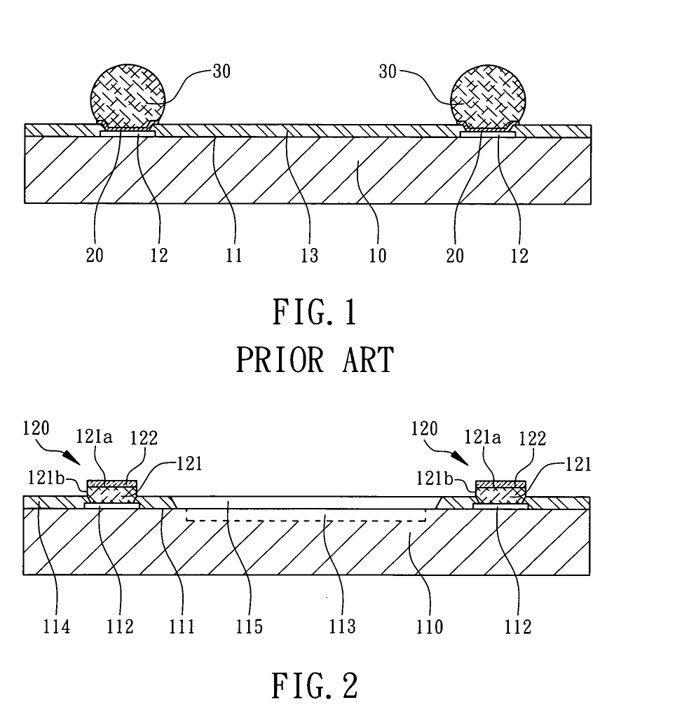

### DETAIL DESCRIPTION OF THE INVENTION

Please refer to the attached drawings, the present invention will be described by means of embodiment(s) below.

In this embodiment according to the present invention, the bump structure of an image sensor chip is an IC device. As shown in FIG. 2, the IC device comprises an opto-electronic chip 110 and a plurality of multi-level bumps 120. The opto-electronic chip 110 has an active surface 111 and a plurality of bonding pads 112 on the active surface 111. Moreover, the active surface 111 includes a photoelectric effecting region 113 which is composed of a plurality of opto-electronic cells such as photodiodes (not shown in the drawing). The opto-electronic chip 110 can be selected from a group consisting of CCD image sensors, CMOS image sensors, LCOS image projecting chip and DLP image processing chips. A photoelectric effecting region 113 is located at the center of the active surface 111, and the bonding pads 112 at the peripheries of the active surface 111. Furthermore, the opto-electronic chip 110 includes a passivation layer 114 such as PI or PSG formed on the active surface 111 with the bonding pads 112 exposed. In the present embodiment, the opto-electronic chip 110 is a CMOS image sensor chip. The passivation layer 114 has an opening 115 aligned with the photoelectric effecting region 113 to achieve a higher transparence and a better clarity.

Please refer to FIG. 2, disposed on the bonding pads 112 are a plurality of multi-level bumps 120. Each has a multi-level structure which comprises at least an and an electroless-plated gold layer 122, wherein all of the electroless-plated nickel layers 121 are formed on a first level, and all of the electroless-plated gold layers 122 are formed on a second level. The nickel layers 121 cover the bonding pads 112, and the gold layers 122 are formed on tops of the nickel layers 121. Moreover, the thickness of the nickel layers 121 is larger than that of the gold layers 122. Preferably, the thickness of the nickel layers 121 is twice thicker than that of the gold layers 122 by means of several times of electroless nickel plating. Therefore, there is no need of any UBM layer disposed between the multi-level bumps 120 and the bonding pads 112 and in the opening 115 of the passivation layer 114 due to the electroless-plating processes. The contaminations or damages to the photoelectric effecting region 113 due to UBM sputtering and reflowing processes can be eliminated. Due to the fabrication processes of bumps 120, the gold layers 122 formed on the tops 121a of the nickel layers 121 do not cover the sidewalls 121b of the nickel layers 121. In this embodiment, the gold layers 122 can fully cover the tops 121a of the nickel layers 121 using a same dry film or photoresist.

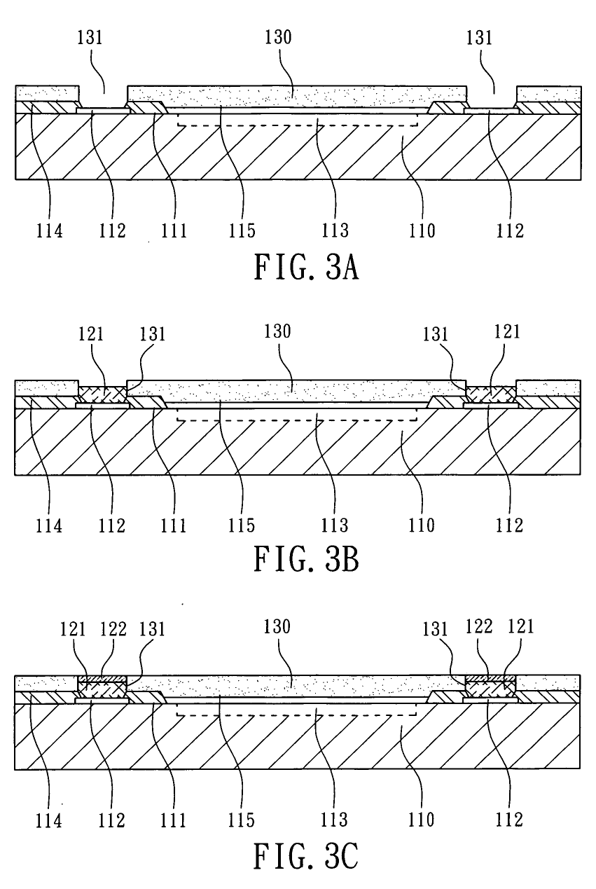

The fabrication processes of the multi-level bumps 120 are described from FIG. 3A to FIG. 3C. In FIG. 3A, a photo-sensitive mask 130 is disposed over the active surface 111 of the opto-electronic chip 110, such as dry films or photo resists. Preferably, the photo-sensitive mask 130 is a dry film to protect the photoelectric effecting region 113. After exposure and development, the photo-sensitive mask 130 has a plurality of openings 131 to expose the bonding pads 112. Then, as shown in FIG. 3B, the nickel layers 121 on a first level are electroless-plated in the openings 131 to bond to the bonding pads 112 directly. The bonding pads 112 may be Aluminum (Al) pads. Normally a zincation layer, not shown in the drawing, is formed on the bonding pads 112 prior to electroless nickel plating processes for preventing from oxidation of the Al bonding pads 112. Then, in FIG. 3C, using the same photo-sensitive mask 130, the gold layers 122 on a second level higher than the first level are formed on tops of the nickel layers 121 by another electroless-plating processes. After removing the photo-sensitive mask 130, a plurality of multi-level bumps 120 are formed on the opto-electronic chip 110 without contaminating or damaging the photoelectric effecting region 113. Moreover, the electrical properties of the bump structure will greatly enhance due to the shorter trace length. Various kinds of packaging types for the opto-electronic chip 110 can be derived from the bump structure such as flip chip bonding, inner lead bonding, and anisotropic conductive bonding using ACP or ACF. Furthermore, at least one level of the electroless nickel layers 121 can perform stand-off characteristic of the multi-level bumps 120 and reduce the cost of the bumps.

The above description of embodiments of this invention is intended to be illustrative and not limiting. Other embodiments of this invention will be obvious to those skilled in the art in view of the above disclosure.

What is claimed is:

1. An IC device comprising:
an opto-electronic chip having an active surface on which a plurality of bonding pads are formed, wherein the active surface includes a photoelectric effecting region;
a plurality of multi-level bumps disposed on the bonding pads, each comprising at least an electroless-plated nickel layer and an electroless-plated gold layer, wherein the nickel layers cover the corresponding bonding pads, and the gold layers are formed on tops of the nickel layers, wherein the thickness of the nickel layers is larger than that of the gold layers.

2. The device of claim 1, wherein the opto-electronic chip is an image sensor chip.

3. The device of claim 1, wherein the nickel layers have a plurality of sidewalls exposed from the gold layers.

4. The device of claim 1, wherein the thickness of the nickel layers is twice thicker than that of the gold layers.

5. The device of claim 1, wherein the photoelectric effecting region is located at the center of the active surface, and the bonding pads are located at the peripheries of the active surface.

6. The device of claim 1, wherein the opto-electronic chip includes a passivation layer formed on the active surface of the opto-electronic chip.

7. The device of claim 6, wherein the passivation layer has an opening aligned with the photoelectric effecting region.

8. The device of claim 1, further comprising a photo-sensitive mask over the active surface, which defines the locations of the multi-level bumps.

9. The device of claim 8, wherein the photo-sensitive mask has a plurality of openings for forming the electroless-plated nickel layers and the electroless-plated gold layers inside.

10. The device of claim 8, wherein the photo-sensitive mask is selected from the group consisting of a dry film and a photo resist.

11. The device of claim 1, wherein the bonding pads are Aluminum (Al) pads.
